(19) United States
(12) Patent Application Publication
(10) Pub. No.: US 2012/0093617 A1
(43) Pub. Date: Apr. 19, 2012

(54) VACUUM PROCESSING APPARATUS AND VACUUM PROCESSING METHOD

(75) Inventors: Yutaka Kudou, Kudamatsu (JP); Hiroaki Takikawa, Fujisawa (JP); Takahiro Shimomura, Kudamatsu (JP); Masakazu Isozaki, Shunan (JP); Takashi Uemura, Kudamatsu (JP)

(73) Assignee: Hitachi High-Technologies Corporation

(21) Appl. No.: 13/011,041

(22) Filed: Jan. 21, 2011

(30) Foreign Application Priority Data
Oct. 18, 2010 (JP) 2010-233192

(51) Int. Cl. H01L 21/67

(52) U.S. Cl. 414/222.01; 414/806

(57) ABSTRACT

A vacuum processing apparatus including a processing chamber for processing a sample to be processed, a cooling chamber for cooling the high-temperature sample processed in the processing chamber, and a vacuum transfer chamber for establishing a connection between the processing chamber and the cooling chamber, a vacuum transfer robot equipped inside the vacuum transfer chamber, wherein the cooling chamber includes a gas-exhausting unit for reducing pressure inside the cooling chamber, a gas-supplying unit for supplying a gas into the cooling chamber, a pressure-controlling unit for controlling the pressure inside the cooling chamber, a supporting unit for supporting the high-temperature sample, and a mounting stage for proximity-holding the sample supported by the supporting unit, the mounting stage having a temperature-adjusting unit for adjusting the temperature of surface of the mounting stage into a temperature which is capable of cooling the high-temperature sample, the supporting unit having an ascending/descending-speed varying unit.

### BACKGROUND OF THE INVENTION

The present invention relates to a vacuum processing apparatus and a vacuum processing method. More particularly, it relates to a vacuum processing apparatus and a vacuum processing method for cooing a high-temperature sample to be processed.

In a multi-chamber-schemed vacuum processing apparatus for machining such samples as a semiconductor material, and in a wafer cooling method for cooling a wafer which has undergone various types of discharges whose plasma processing schemes are different from each other, or a wafer which has undergone a heat treatment, the following wafer cooling structures or methods have become necessary: namely, a cooling method wherein the high throughput specific to the multi-chamber scheme is taken into consideration, or a cooling structure or method wherein there occurs none of the reactive particles, metal contamination, or cross contamination (i.e., mutual pollution) which are caused to occur by an outgas between wafers whose processing chambers are different from each other. Meanwhile, with respect to an originally-purposed wafer cooling apparatus which is provided additionally to a plasma processing chamber or heat treatment chamber, it must be avoided to provide a complicated structure or mechanism as this cooling apparatus. This is because its main purpose is to execute the cooling operation, and because the complicated structure or mechanism becomes a cause for increasing its apparatus cost.

When basically classified, there exist two types of conventional wafer cooling methods, i.e., a wafer cooling method wherein an electrostatic chuck is used, and one wherein an electrostatic chuck is not used. First, as the wafer cooling method wherein the electrostatic chuck is not used, in JP-A-2007-73564, there is disclosed a wafer cooling method in which a cooling gas is sprayed over the high-temperature wafer and then the wafer is mounted on a stage which has been already cooled. Also, in JP-A-2001-319885, there is disclosed a wafer cooling method in which an inert gas is sprayed over the high-temperature wafer while mounting the wafer on a pusher pin. Meanwhile, as the wafer cooling method wherein the electrostatic chuck is used, in JP-A-6-326181, there is disclosed a wafer cooling method in which the surface of an electrode, which is supposed to come into contact with the high-temperature wafer, is mirror-finished without taking advantage of the inert gas.

### SUMMARY OF THE INVENTION

While the wafer remains in the high-temperature state, some extent of cooling effect is available only with execution of the cooling at a position up to which the pusher is caused to ascend. Nevertheless, as the wafer's temperature becomes lower, the cooling effect also becomes less in accompaniment therewith. This fact requires an additional employment of the cooling implemented by mounting the wafer on the stage, or the cooling implemented by proximity-holding the wafer. In the semiconductor-device fabrication process in recent years, however, severity has been requested not only for the management of the particles and contamination on the wafer's surface, but also for the management of the particles and contamination on the wafer's rear surface. Accordingly, when the management of the particles and contamination on the wafer's rear surface is taken into consideration, the wafer cooling method wherein no electrostatic chuck is used becomes desirable as the method for executing the cooling implemented by mounting the wafer on the stage, or the cooling implemented by proximity-holding the wafer. In the wafer cooling method wherein no electrostatic chuck is used, however, a wafer displacement in the transverse direction is caused to occur in accordance with the following way. At the time of mounting the wafer on the stage, when the cooling gas is supplied thereto, the pressure in the surroundings around the wafer has been already raised. Then, when the wafer is brought into contact with the stage's surface in the high-pressure state, the descending of the wafer which is mounted on the pusher gives rise to occurrence of a hovering phenomenon, where the gas on the lower side is compressed. This compression of the lower-side gas gives rise to the occurrence of the above-described wafer displacement in the transverse direction. Then, this wafer displacement brings the wafer into contact with the stage's circumference, thereby giving rise to the creation of the particles, a wafer cracking (i.e., chipping), and other issues. In the conventional technologies, however, no consideration has been given to the prevention and suppression of the wafer displacement which becomes a cause for the creation of the particles. In view of this situation, an object of the present invention is so selected as to provide a vacuum processing apparatus and a vacuum processing method which make it possible to cool the high-temperature wafer quickly, and to prevent and suppress the creation of the particles caused by the wafer displacement.

In the present invention, there is provided a vacuum processing apparatus including a processing chamber for processing a sample to be processed, a cooling chamber for cooling the high-temperature sample processed in the processing chamber, and a vacuum transfer chamber for establishing a connection between the processing chamber and the cooling chamber, a vacuum transfer robot being set up inside the vacuum transfer chamber, wherein the cooling chamber includes a gas-exhausting unit for reducing pressure inside the cooling chamber, a gas-supplying unit for supplying a gas into the cooling chamber, a pressure-controlling unit for controlling the pressure inside the cooling chamber, a supporting unit for supporting the high-temperature sample, and a mounting stage for proximity-holding the sample supported by the supporting unit, the mounting stage having a temperature-adjusting unit for adjusting the temperature of surface of the mounting stage into a temperature which is capable of cooling the high-temperature sample, the supporting unit having an ascending/descending-speed varying unit.

According to the present invention, it becomes possible to cool the high-temperature wafer quickly, and to prevent and suppress the creation of the particles caused by the wafer displacement.

Other objects, features and advantages of the invention will become apparent from the following description of the embodiments of the invention taken in conjunction with the accompanying drawings.

### BRIEF DESCRIPTION OF THE DRAWINGS

FIG. 1A is a schematic diagram of a vacuum processing apparatus in a first embodiment, and FIG. 1B is a longitudinal cross-sectional diagram of a cooling chamber;

FIG. 2A is a schematic diagram of the stage;

FIG. 2B is a schematic diagram of an O-ring groove around the pusher;

FIG. 2C is a schematic diagram of an O-ring groove at an outer-circumferential portion of the stage;

FIG. 2D is a longitudinal cross-section diagram of the O-ring groove at the outer-circumferential portion of the stage;

FIG. 3 is a diagram for illustrating the experimental relationship between the pressure inside the cooling chamber and a wafer displacement amount with respect to a pusher-descending speed;

FIG. 4 is a diagram for explaining the adjustment of a proximate distance using O rings;

FIG. 5 is a diagram for illustrating the pressure inside a cooling chamber 1 with respect to each step of a cooling flow according to a cooling method (1);

FIG. 6A is a schematic diagram of the cooling flow according to the cooling method (1) when a high-temperature wafer is transferred into the cooling chamber;

FIG. 6B is a schematic diagram of the cooling flow according to the cooling method (1) when the cooling gas is introduced;

FIG. 6C is a schematic diagram of the cooling flow according to the cooling method (1) when the wafer is proximity-held over the cooling stage;

FIG. 7 is a diagram for explaining a measurement method for a cooling rate;

FIG. 8 is a diagram for illustrating the pressure in the cooling chamber 1 with respect to each step of a cooling flow according to a cooling method (2);

FIG. 9A is a schematic diagram of the cooling flow according to the cooling method (2) when the high-temperature wafer is transferred into the cooling chamber;

FIG. 9B is a schematic diagram of the cooling flow according to the cooling method (2) when the wafer is proximity-held over the cooling stage;

FIG. 9C is a schematic diagram of the cooling flow according to the cooling method (2) when the cooling gas is introduced;

FIG. 10 is a diagram for illustrating the pressure in the cooling chamber 1 with respect to each step of a cooling flow according to a cooling method (3);

FIG. 11A to FIG. 11C are schematic diagrams of the cooling flow according to the cooling method (3); and

FIG. 11A is a schematic diagram of the cooling flow according to the cooling method (3) when the high-temperature wafer is transferred into the cooling chamber;

FIG. 11B is a schematic diagram of the cooling flow according to the cooling method (3) when the cooling chamber is being pumped down while the wafer is held in the cooling chamber;

FIG. 11C is a schematic diagram of the cooling flow according to the cooling method (3) when the wafer is mounted onto the cooling stage and, then later, the cooling gas is introduced;

FIG. 12 is a schematic diagram of the vacuum processing apparatus in a second embodiment.

### DESCRIPTION OF THE INVENTION

### Embodiment 1

Hereinafter, referring to the drawings, the explanation will be given below concerning an embodiment of the present invention.

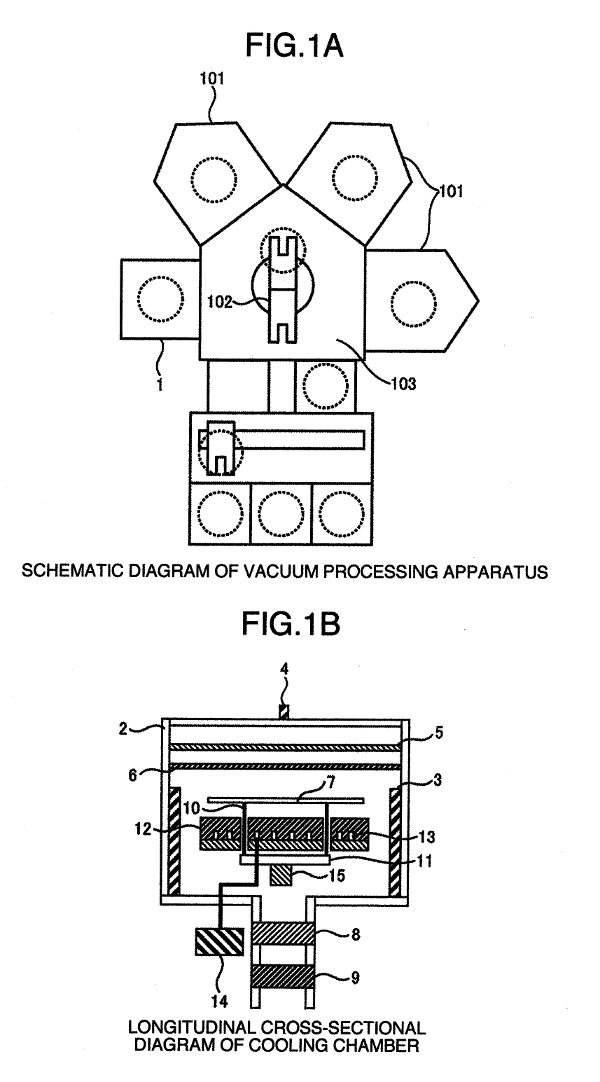

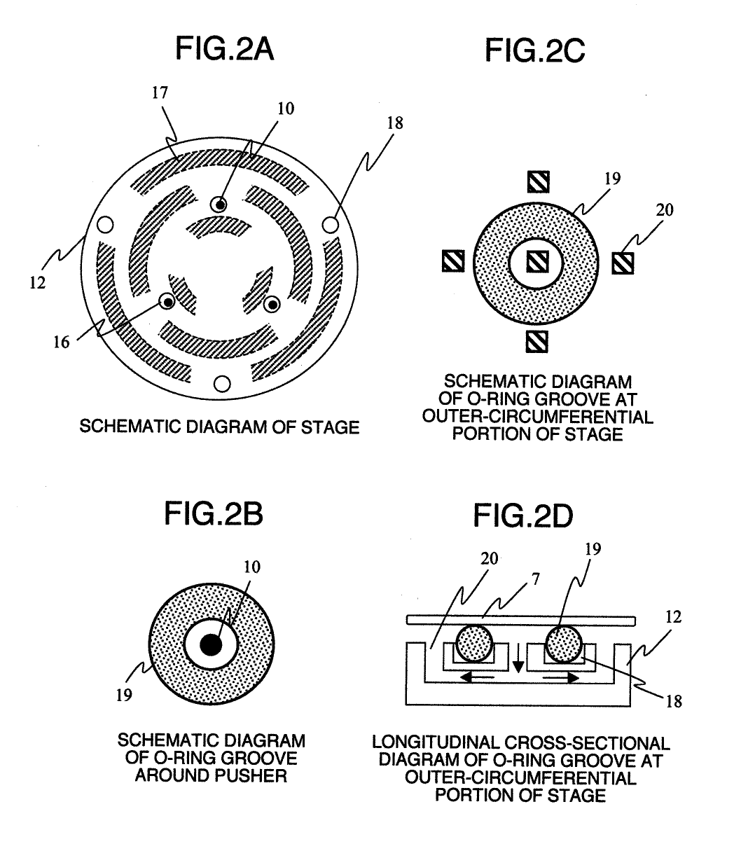

FIG. 1A is a schematic diagram of a vacuum processing apparatus in the present first embodiment. Multiple plasma processing chambers and heat treatment chambers 101 (described as processing chambers, hereinafter) are connected to a vacuum transfer chamber 103, in which a vacuum transfer robot 102 is equipped. In this embodiment, a cooling chamber 1 of the present invention is attached to the vacuum transfer chamber 103. FIG. 1B is a longitudinal cross-sectional diagram of the cooling chamber 1. FIG. 2A to FIG. 2D are schematic diagrams of a stage 12, which is a mounting stage set up inside the cooling chamber 1. FIG. 2A is a schematic diagram of the stage 12. FIG. 2B is a schematic diagram of an O-ring groove around the pusher. FIG. 2C is a schematic diagram of an O-ring groove at an outer-circumferential portion of the stage 12. FIG. 2D is a longitudinal cross-section diagram of the O-ring groove at the outer-circumferential portion of the stage 12.

The cooling chamber 1 includes an aluminum-composed vacuum chamber 2. A quarts-composed sleeve 3, which is of a detachable/attachable structure, is set up inside the vacuum chamber 2. On account of this detachable/attachable structure, when the sleeve 3 becomes dirty by an outgas generated from a wafer 7, i.e., a sample to be processed, at the time of the cooling processing for the wafer 7, the sleeve 3 can be cleaned by being removed from the vacuum chamber 2. Also, a cooling gas is introduced from a gas-supplying inlet 4 positioned at an upper portion of the cooling chamber 1. Moreover, the cooling gas is primarily-dispersed by an aluminum-composed shower plate 5, and further, is secondarily-dispersed by a quarts-composed shower plate 6, then being supplied into the cooling chamber 1. In this aluminum-composed shower plate 5 used for primary dispersion, the hole diameter of its gas-supplying holes (not illustrated) is smaller, and the number of these gas-supplying holes is larger as compared with the quarts-composed shower plate 6 used for secondary dispersion. As a result, the gas to be supplied into the cooling chamber 1 can be supplied perpendicularly to the entire surface of the wafer 7. This feature allows the wafer 7 to be cooled uniformly within its entire surface.

In the cooling-gas supply operation, at least one or more species of cooling gas can be supplied into the cooling chamber 1 from the gas-supplying inlet 4 in a manner of a single element or a mixture. Although, in the present embodiment, a high-cooling-effect-exhibiting helium gas is employed as the cooling gas, the other inert gas, such as argon, nitrogen, or xenon, is also employable. In the gas exhaust operation, the cooling gas is exhausted by using a high-pumping-speed dry pump 9 from a lower portion of the cooling chamber 1 via a pressure-adjusting valve 8. Namely, the cooling-gas exhaust operation is structured such that the cooling gas introduced from the upper portion of the cooling chamber 1 resides uniformly inside the cooling chamber 1, and is then exhausted.

The wafer 7 is supported by three pieces of pushers 10. The front ends of these pushers 10 are made planar so that the wafer 7 on the pushers 10 is horizontally maintained with a high accuracy. Also, a supporter 11 for supporting the three pieces of pushers 10 is connected to a motor 15 which is capable of arbitrarily changing the ascending/descending speed of the supporter 11 and the pushers 10. Furthermore, the mechanism of these pushers 10 is designed as follows. Namely, when performing the descending operation of the wafer 7, these pushers 10 make it possible to cause the wafer 7 to descend onto the stage 12 with an a pitch of approximately 0.5-mm, and within a height range of 0.1-mm to 2.0-mm from the surface of the stage 12.

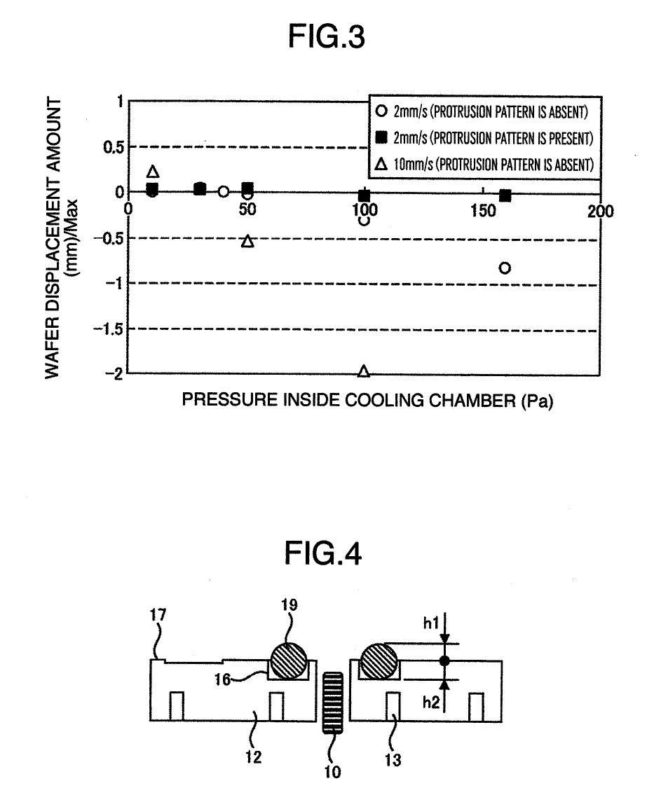

A cooling-medium introduction pipe 13 for circulating a cooling medium is built in the stage 12 for cooling the wafer 7. A circulator 14 makes it possible to control the temperature of the stage 12 within a 10-° C. to 50-° C. temperature range. Also, the machining of a 500-μm-height protrusion pattern 17 is applied onto the surface of the stage 12. The total area of this protrusion pattern 17 is an area in which the contact ratio of the surface of the stage 12 with respect to the area of the wafer 7 becomes equal to 50% or less. Even if the pressure inside the cooling chamber 1 is equal to 2000 Pa or higher, the machining of the above-described protrusion pattern 17 applied onto the surface of the stage 12 prevents a wafer displacement from being caused to occur when the wafer 7 is mounted on the stage 12. FIG. 3 is a diagram for illustrating the experimental relationship between the pressure inside the cooling chamber 1 and a wafer displacement amount with respect to a pusher-descending speed. Incidentally, this experiment has been made as follows. An argon gas is supplied to the cooling chamber 1 with the wafer 7 mounted on the pushers 10, and then mounting the wafer 7 on the stage 12. Subsequently, the wafer displacement caused to occur at this time is measured using a CCD camera. In this experiment, it has been found successful to confirm that in the stage 12 onto whose surface the machining of the 500-μm-height protrusion pattern 17 has been applied, the wafer displacement is prevented from being caused to occur even if the pressure inside the cooling chamber 1 is equal to 2000 Pa or higher.

Also, on the stage 12, as illustrated in FIG. 2A to FIG. 2D, O-ring grooves 16 are made at peripheries of three holes of the pushers 10. Simultaneously, O-ring grooves 18 are made at the outer-circumferential portion of the stage 12. Also, when the wafer 7 is mounted on the stage 12, a gas generated from an O ring 19 raises the pressure inside a space positioned on the inner side of the O ring 19 underneath of the wafer 7. This rise in the pressure on the inner side of the O ring 19 causes a wafer displacement to occur in each O-ring groove 18 set up at the outer-circumferential portion of the stage 12. Accordingly, there is provided a gas-exhausting hole 20 for lowering the pressure on the inner side of the O ring 19. On account of this gas-exhausting hole 20, the inner side of the O ring 19 set up at the outer-circumferential portion of the stage 12 is brought into a non-hermetically-sealed state. As a result, there occurs none of the wafer displacement caused by the gas-pressure rise due to the O ring 19. Incidentally, concerning each O-ring groove 16 setup on the peripheral portion of each pusher 10, there exists the space for implementing the ascending/descending of each pusher 10. Consequently, there occurs none of the rise in the gas pressure inside the space positioned on the inner side of the O ring 19. Also, as illustrated in FIG. 4, by taking advantage of a hump h1 of the O ring 19 in each O-ring groove 16, it becomes possible to adjust the distance for implementing the proximity holding between the wafer 7 and the stage 12. Incidentally, the proximity holding means that the wafer 7 is held over the stage 12 at the 0.1-mm to 2.0-mm height from the surface of the stage 12. Also, the hump h1 of the O ring 19 can be adjusted by deepening a depth h2 of each O-ring groove 16. Regarding the above-described proximity holding, the configuration is basically the same in each O-ring groove 18 as well.

The present first embodiment is an embodiment where both of the protrusion pattern 17 and the O-ring grooves 16 and 18 are set up on the stage 12. It is also allowable, however, that either of the protrusion pattern 17 and the O-ring grooves 16 and 18 is set up on the stage 12. Next, the explanation will be given below concerning a wafer cooling method according to the present invention.

When basically classified, the wafer cooling method according to the present invention is classified into two types, i.e., a cooling method based on the proximity holding and a cooling method based on the mounting of the wafer on the stage 12. Moreover, the above-described proximity-holding-based cooling method is further classified into two types. Accordingly, when precisely classified, the wafer cooling method according to the present invention turns out to be the three types in total. Incidentally, the above-described proximity holding means that the wafer 7 is held at the 0.1-mm to 2.0-mm height from the surface of the stage 12. The selection and employment of a 0.1-mm-or-less height makes it impossible for the gas, which would cause the hovering phenomenon, to obtain a space through which the gas can escape easily. Meanwhile, the selection and employment of a 2.0-mm-or-higher height drops the cooling effect on the wafer 7 extremely. Also, the method for implementing the proximity holding is classified into the following three types: Method A: a method using the protrusion pattern 17, Method B: a method using the O rings 19, and Method C: a method using the pushers 10. The method using the pushers 10, i.e., Method C, is a method where the wafer 7 is held in such a manner that the height of the front ends of the pushers 10 is set at the 0.1-mm to 2.0-mm height from the surface of the stage 12. Also, as the proximity-holding implementing method, a combination of these three methods is also allowable without being limited to the employment of any one of them.

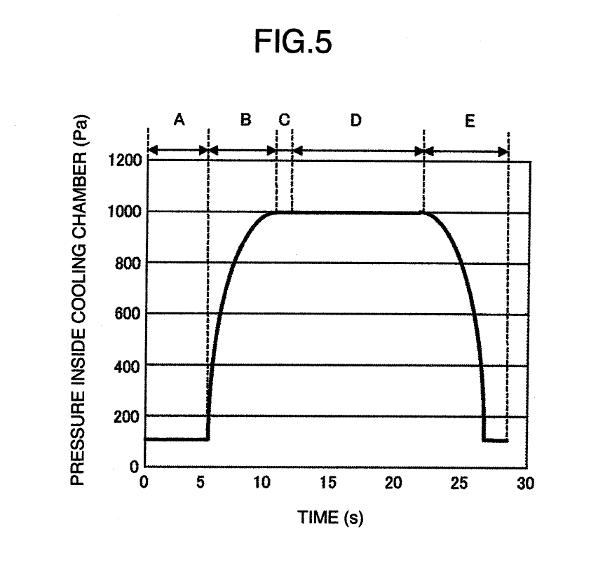

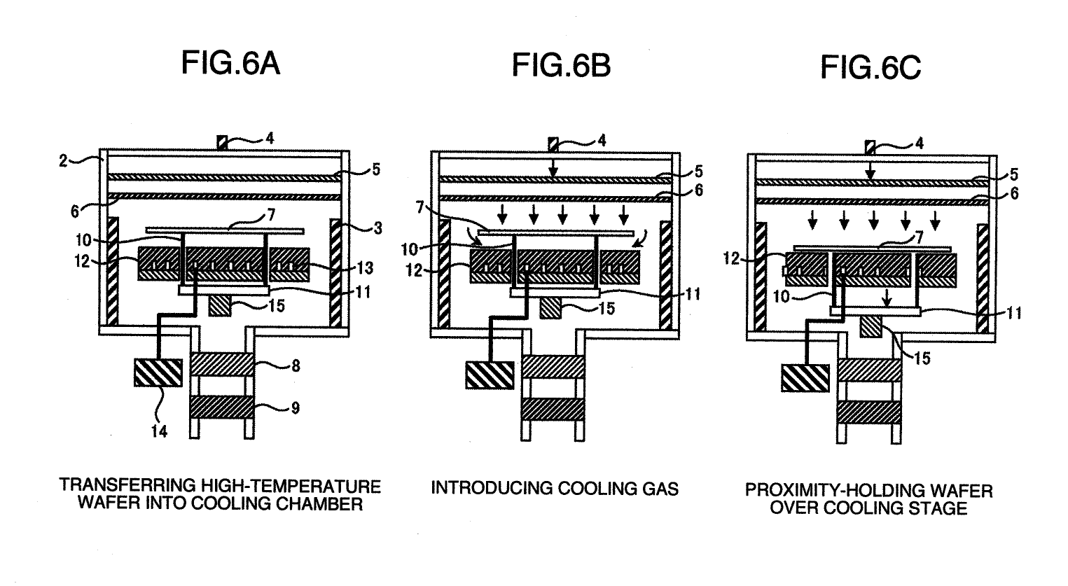

First of all, the explanation will be given below concerning “cooling method (1)”, i.e., the first method of the proximity-holding-based cooling methods. FIG. 5 is a diagram for illustrating the pressure inside the cooling chamber 1 with respect to each step of the cooling flow according to the cooling method (1). Also, FIGS. 6A, 6B, and 6C are schematic diagrams of the cooling flow according to the cooling method (1). The present cooling method (1) is executed as follows. A gate valve (not illustrated) is opened which is capable of hermetically blocking and opening/closing the boundary between the cooling chamber 1 and the vacuum transfer chamber 103. Next, the high-temperature wafer 7, which is processed in one of the processing chambers 101, is transferred into the cooling chamber 1 by the vacuum transfer robot 102, then being mounted onto the pushers 10. After the wafer 7 has been mounted onto the pushers 10, the vacuum transfer robot 102 is transferred out of the cooling chamber 1, then closing the above-described gate valve (not illustrated) (Step A). The relative distance between the wafer 7 and the surface of the stage 12 at this time is a few-mm to 30-mm distance. The ensuring of this extent of relative distance permits a gas to smoothly intrude into the space between the wafer 7 and the stage 12. This smooth intrusion allows the wafer 7 to be cooled uniformly within its surface in the cooling operation of the wafer 7 where the gas is used as its heat-transfer medium. Next, a helium gas is supplied into the cooling chamber 1 at a 10-litter/min supply rate while the wafer 7 is being mounted on the pushers 10. This operation increases the pressure inside the cooling chamber 1 from 100 Pa to a preset pressure of 1000 Pa. Also, at this time, a first cooling operation of the wafer 7 is executed on the pushers 10 until the pressure inside the cooling chamber 1 has reached 1000 Pa from 100 Pa (Step B). Incidentally, in order to shorten the time-interval which the pressure inside the cooling chamber 1 necessitates for reaching the preset pressure of 1000 Pa, the inside of the cooling chamber 1 is filled with the gas by closing the pressure-adjusting valve 8. However, after the pressure has reached the set pressure, the control is performed so that the set pressure is maintained by the pressure-adjusting valve while continuing to supply the helium gas at the 10-litter/min supply rate. Also, the increasing of the pressure inside the cooling chamber 1 is executed for the purpose of heightening the cooling effect. Also, the pressure is increased for the purpose of causing the helium gas, i.e., the medium for executing the heat transfer between the wafer 7 and the stage 12, to flow around onto the rear-surface side of the wafer 7 at a high speed when the wafer 7 is mounted on the stage 12. Also, although, in the present embodiment, the pressure has been increased up to 1000 Pa, the selection and employment of the pressure in a 400-Pa to 5000-Pa range is also allowable. The selection and employment of a 400-Pa-or-higher pressure makes it possible to obtain the cooling effect that is needed for obtaining the cooling time of an extent which will exert no influence on the processing efficiency in the processing chamber 101. Meanwhile, the selection and employment of a 5000-Pa-or-higher pressure necessitates too much time for increasing the pressure inside the cooling chamber 1, thereby lowering the cooling-processing efficiency. Next, after the pressure inside the cooling chamber 1 has reached 1000 Pa, the pushers 10 are caused to descend. This descending operation of the pushers 10 allows the wafer 7 to be proximity-held over the cooling stage 12 whose temperature is adjusted at 15° C. (Step C). After the wafer 7 has been proximity-held over the cooling stage 12, a second cooling operation of the wafer 7 is started, thereby cooling the wafer 7 until the temperature or time has reached a predetermined temperature or time (Step D). After the second cooling operation has been completed, the pushers 10 are caused to ascend up to a passing position of the wafer 7 to the vacuum transfer robot 102. This ascending operation of the pushers 10 is executed while reducing the pressure inside the cooling chamber 1 down to 100 Pa by stopping the supply of the helium gas into the cooling chamber 1. Moreover, after confirming that the pressure inside the cooling chamber 1 has reached 100 Pa, the above-described gate valve (not illustrated) is opened. Furthermore, the wafer 7 cooled in this way is transferred out of the cooling chamber 1 by the vacuum transfer robot 102, then closing the above-described gate valve (Step E). Incidentally, although the set temperature for the cooling stage 12 according to the present method has been set at 15° C., the selection and employment of the temperature in a 5-° C. to 50-° C. range is allowable. The selection and employment of a 5-° C.-or-lower temperature gives rise to a possibility that the wafer 7 will be condensed. Accordingly, this temperature is unemployable. Meanwhile, the selection and employment of a 50-° C.-or-higher temperature makes it difficult to implement the desired cooling effect.

Also, in FIG. 5, the pressure at the time when the wafer 7 is transferred from the vacuum transfer chamber 103 into the cooling chamber 1 is set at 100 Pa. The vacuum transfer chamber 103 is always maintained at this pressure by always supplying the inert gas, such as argon or nitrogen, into the vacuum transfer chamber 103 in order to reduce the creation of particles. Here, the gate valve (not illustrated) is capable of hermetically blocking and opening/closing the boundary between the vacuum transfer chamber 103 and the cooling chamber 1 at the time when the wafer 7 is transferred into/out of the cooling chamber 1. Therefore, in order to avoid variations in the pressure of the vacuum transfer chamber 103 even when the gate valve is opened, the pressure of the cooling chamber 1 is set at this pressure when the wafer 7 is transferred between the vacuum transfer chamber 103 and the cooling chamber 1.

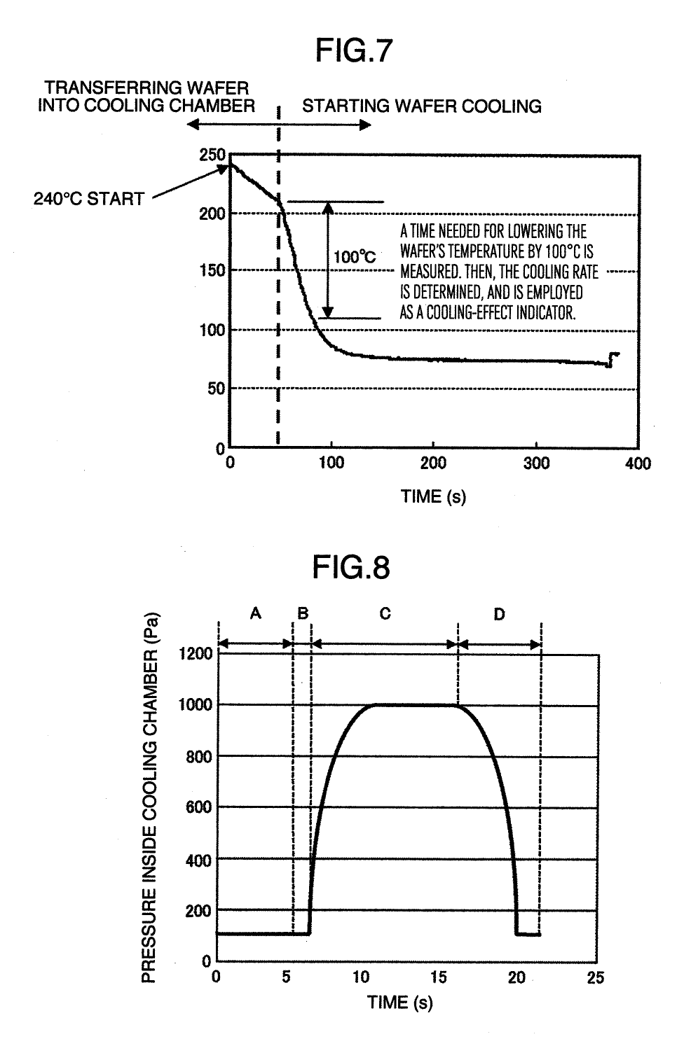

Next, the explanation will be given below regarding the cooling effect exhibited by the cooling method (1). Incidentally, as an indicator for indicating the cooling effect, the cooling rate is calculated and investigated. FIG. 7 is a diagram for explaining a measurement method for measuring the cooling rate in the present embodiment. Taking advantage of a radiation thermometer, the measurement has been made concerning the following temperature change. The temperature change ranging from the state where the wafer 7 heated at 250° C. in the heat treatment chamber 101 is transferred into the cooling chamber 1, until a state where the surface temperature of the wafer 7 becomes saturated by being cooled by the cooling method of the present invention. Moreover, based on this measurement method, the cooling rate is determined as a value which is calculated based on a time-interval elapsing from the point-in-time when the supply of the cooling gas into the cooling chamber 1 is started until a point-in-time when the surface temperature of the wafer 7 becomes equal to 100° C. Then, this cooling rate is employed as the indicator for indicating the cooling effect.

The resultant cooling rate acquired by the present cooling method has been found to be 10° C./sec. Also, as a result of having evaluated the gas-specie dependence of the cooling effect on the helium gas, nitrogen gas, and helium-and-nitrogen mixture gas, the gas which has resulted in the exhibition of the largest cooling effect has been found to be the helium gas.

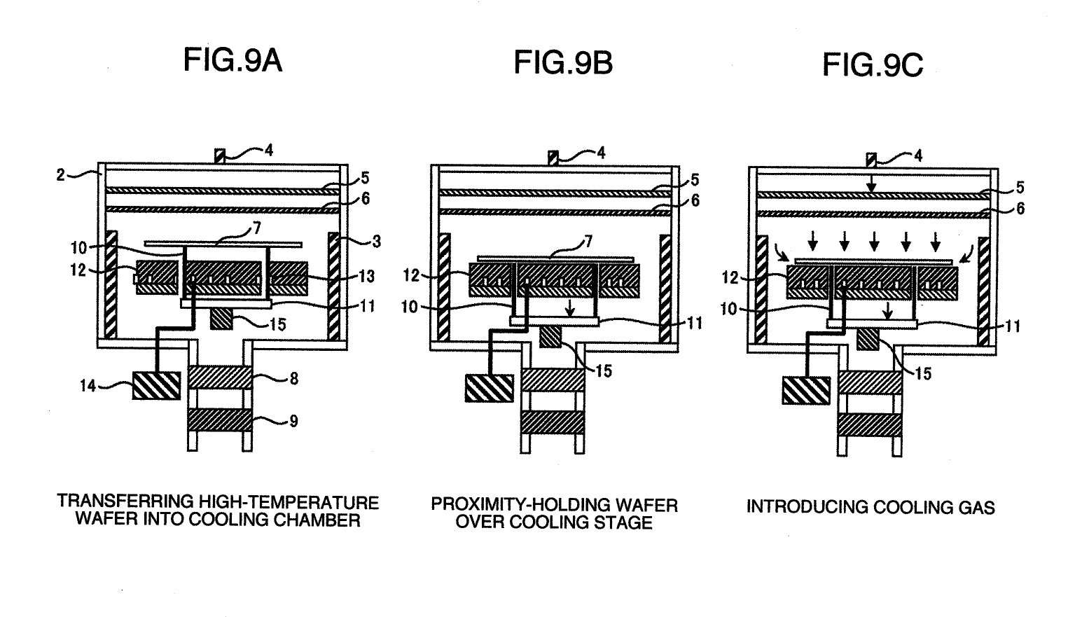

Next, the explanation will be given below concerning “cooling method (2)”, i.e., the second method of the proximity-holding-based cooling methods. FIG. 8 is a diagram for illustrating the pressure inside the cooling chamber 1 with respect to each step of the cooling flow according to the cooling method (2). Also, FIGS. 9A, 9B, and 9C are schematic diagrams of the cooling flow according to the cooling method (2). The present cooling method (2) is executed as follows. The gate valve (not illustrated) is opened which is capable of hermetically blocking and opening/closing the boundary between the cooling chamber 1 and the vacuum transfer chamber 103. Next, the high-temperature wafer 7, which is processed in the processing chamber 101, is transferred into the cooling chamber 1 by the vacuum transfer robot 102, then being mounted onto the pushers 10. After the wafer 7 has been mounted onto the pushers 10, the vacuum transfer robot 102 is transferred out of the cooling chamber 1, then closing the above-described gate valve (not illustrated) (Step A). Next, in a state where the pressure inside the cooling chamber 1 is made equal to 100 Pa, the pushers 10 are caused to descend. This descending operation of the pushers 10 allows the wafer 7 to be proximity-held over the cooling stage 12 whose temperature is adjusted at 15° C. A first cooling operation of the wafer 7 is executed from the point-in-time when the pushers 10 start to descend until a point-in-time when the supply of the helium gas into the cooling chamber 1 is started (Step B). Incidentally, although the set temperature for the cooling stage 12 according to the present method has been set at 15° C., the selection and employment of the temperature in a 5-° C. to 50-° C. range is allowable. The selection and employment of a 5-° C.-or-lower temperature gives rise to a possibility that the wafer 7 will be condensed. Accordingly, this temperature is unemployable. Meanwhile, the selection and employment of a 50-° C.-or-higher temperature makes it difficult to implement the desired cooling effect. Subsequently, a second cooling operation of the wafer 7 is started by supplying the helium gas so that the pressure inside the cooling chamber 1 reaches 1000 Pa. In this way, the wafer 7 is cooled until the temperature or time has reached a predetermined temperature or time (Step C). Incidentally, although, in the present embodiment, the pressure has been increased up to 1000 Pa, the selection and employment of the pressure in a 400-Pa to 5000-Pa range is also allowable. The selection and employment of a 400-Pa-or-higher pressure makes it possible to obtain the cooling effect that is needed for obtaining the cooling time of an extent which will exert no influence on the processing efficiency in the processing chamber 101. Meanwhile, the selection and employment of a 5000-Pa-or-higher pressure necessitates too much time for increasing the pressure inside the cooling chamber 1, thereby lowering the cooling-processing efficiency. Next, after the second cooling operation has been completed, the pushers 10 are caused to ascend up to the passing position of the wafer 7 to the vacuum transfer robot 102. This ascending operation of the pushers 10 is executed while reducing the pressure inside the cooling chamber 1 down to 100 Pa by stopping the supply of the helium gas into the cooling chamber 1. Moreover, after confirming that the pressure inside the cooling chamber 1 has reached 100 Pa, the above-described gate valve (not illustrated) is opened. Furthermore, the wafer 7 cooled in this way is transferred out of the cooling chamber 1 by the vacuum transfer robot 102, then closing the above-described gate valve (Step D). The resultant cooling rate acquired by the present cooling method using the helium gas has been found to be 12° C./sec.

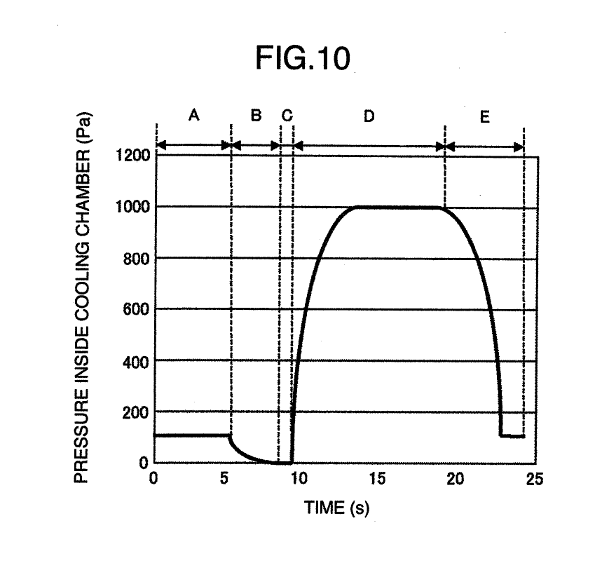

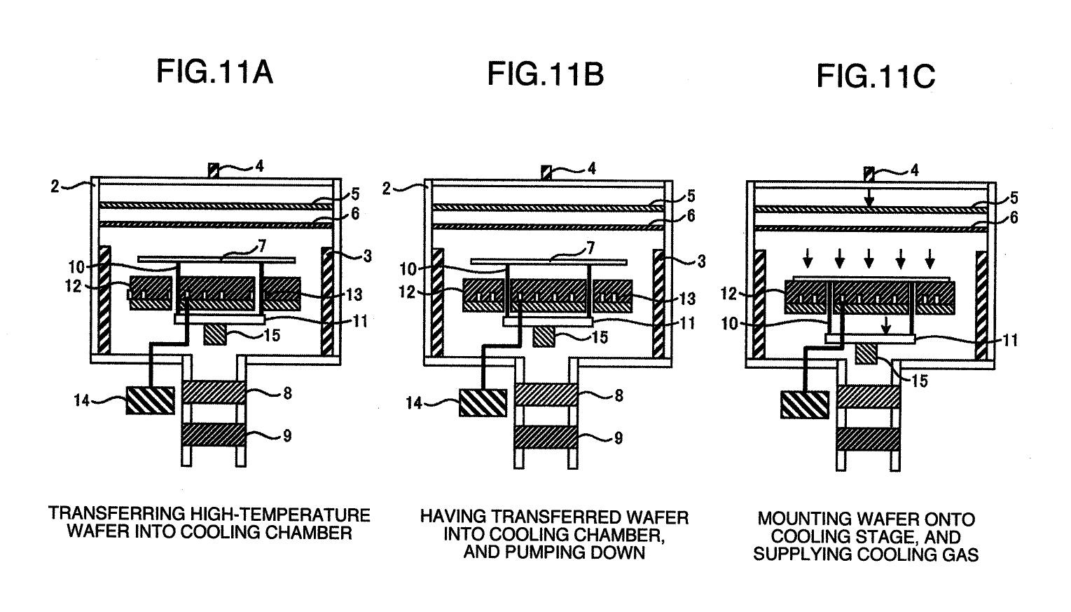

Next, the explanation will be given below regarding “cooling method (3)”, i.e., the cooling method wherein the wafer 7 is cooled by mounting the wafer 7 onto the stage 12 (i.e., by bringing the wafer 7 into contact with the stage 12). In the present cooling method (3), it is required to bring the wafer 7 into contact with the stage 12. Accordingly, the protrusion pattern 17 and the O-ring grooves 16 and 18 are not set up on the surface of the stage 12. The surface of the stage 12, however, is subjected to a mirror-finish machining. This is because the cooling effect is enhanced by shortening the substantial distance between the rear surface of the wafer 7 and the surface of the stage 12. Also, although it is desirable that the surface of the stage 12 is subjected to the mirror-finish machining, it is also allowable that the surface of the stage 12 is not subjected thereto. Also, FIG. 10 is a diagram for illustrating the pressure inside the cooling chamber 1 with respect to each step of the cooling flow according to the cooling method (3). FIGS. 11A, 11B, and 11C are schematic diagrams of the cooling flow according to the cooling method (3). The present cooling method (3) is executed as follows. The gate valve (not illustrated) is opened which is capable of hermetically blocking and opening/closing the boundary between the cooling chamber 1 and the vacuum transfer chamber 103. Next, the high-temperature wafer 7, which is processed in the processing chamber 101, is transferred into the cooling chamber 1 by the vacuum transfer robot 102, then being mounted onto the pushers 10. After the wafer 7 has been mounted onto the pushers 10, the vacuum transfer robot 102 is transferred out of the cooling chamber 1, then closing the above-described gate valve (not illustrated) (Step A). Next, in the state where the wafer 7 is held on the pushers 10, a vacuum decompression is executed from 100 Pa to 1.0 Pa or lower with respect to the pressure inside the cooling chamber 1 (Step B).

Next, the pushers 10 are caused to descend at a 10-mm/sec speed down to a proximity-holding position (which is at a 0.3-mm height from the surface of the stage 12 in the present method). Subsequently, the pushers 10 are caused to descend at a 2.0-mm/sec speed until the wafer 7 is brought into contact with the stage 12 from the proximity-holding position. This descending operation of the pushers 10 allows the wafer 7 to be mounted onto the stage 12 whose temperature is adjusted at 15° C. The cooling chamber 1 is already pumped down to low pressure when the wafer is lowered down further from the proximity-holding position and the hovering phenomenon, which causes displacement of the wafer 7, is avoided. A first cooling operation of the wafer 7 is executed from the point-in-time when the pushers 10 start to descend until the point-in-time when the wafer 7 is mounted onto the stage 12 (Step C). Incidentally, although the setting temperature for the cooling stage 12 according to the present method has been set at 15° C., the selection and employment of the temperature in a 5-° C. to 50-° C. range is allowable. The selection and employment of a 5-° C.-or-lower temperature gives rise to a possibility that the wafer 7 will be condensed. Accordingly, this temperature is unemployable. Meanwhile, the selection and employment of a 50-° C.-or-higher temperature makes it difficult to implement the desired cooling effect. Subsequently, the pressure inside the cooling chamber 1 is increased up to 1000 Pa by supplying the helium gas. Then, a second cooling operation of the wafer 7 is executed from the point-in-time when the supply of the helium gas is started until the temperature or time has reached a predetermined temperature or time (Step D). Incidentally, although, in the present embodiment, the pressure has been increased up to 1000 Pa, the selection and employment of the pressure in a 400-Pa to 5000-Pa range is also allowable. The selection and employment of a 400-Pa-or-higher pressure makes it possible to obtain the cooling effect that is needed for obtaining the cooling time of an extent which will exert no influence on the processing efficiency in the processing chamber 101. Meanwhile, the selection and employment of a 5000-Pa-or-higher pressure necessitates too much time for increasing the pressure inside the cooling chamber 1, thereby lowering the cooling-processing efficiency. Next, after the second cooling operation has been completed, the pushers 10 are caused to ascend up to the passing position of the wafer 7 to the vacuum transfer robot 102. This ascending operation of the pushers 10 is executed while reducing the pressure inside the cooling chamber 1 down to 100 Pa by stopping the supply of the helium gas into the cooling chamber 1. Moreover, after confirming that the pressure inside the cooling chamber 1 has reached 100 Pa, the above-described gate valve (not illustrated) is opened. Furthermore, the wafer 7 cooled in this way is transferred out of the cooling chamber 1 by the vacuum transfer robot 102, then closing the above-described gate valve (Step E). The resultant cooling rate acquired by the present cooling method when the helium gas is applied has been found to be 17° C./sec.

As having been explained so far, the above-described cooling rates acquired by the three cooling methods of the present invention have allowed accomplishment of the 10-° C./sec-or-greater values. For example, the accomplishment of the 10-° C./sec cooling rate makes it possible to necessitate only 20 seconds to cool a 300-° C.-high-temperature wafer down to 100° C. The cooling time-interval of this level is shorter than the processing time-interval necessitated in the processing chamber 101 for executing the processes such as heat treatment and plasma processing. Accordingly, this cooling processing time-interval of the present invention never becomes a bottleneck in these processes such as heat treatment and plasma processing. Consequently, the use of the cooling methods of the present invention never lowers the throughput of these processes. This feature makes it possible to prevent and suppress the creation of the particles caused by the wafer displacement. Also, with respect to various types of wafers whose processing steps are different from each other, the above-described, proximity-holding-based cooling methods (1) and (2) are selectable depending on the requirements. This feature allows implementation of the optimum cooling processing.

### Embodiment 2

In a general semiconductor fabricating apparatus, a high-temperature wafer, which has already undergone the plasma processing or heat treatment, is transferred out by a transfer robot in a transfer chamber 24. These transfer chamber and transfer robot are also used to handle unprocessed wafers. Accordingly, an outgas generated from the processed wafer diffuses inside the transfer chamber, thereby causing particles to adhere to an unprocessed wafer, or contaminating the unprocessed wafer.

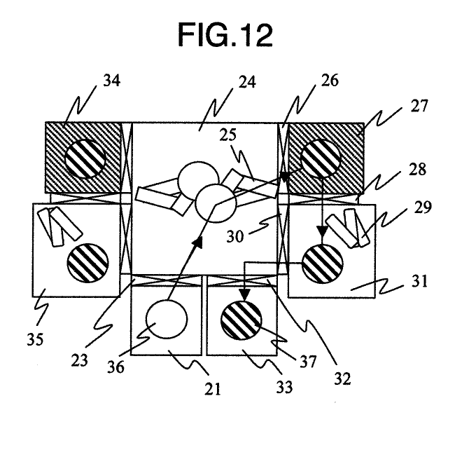

In order to solve this problem, as illustrated in FIG. 12, which is a schematic diagram of the vacuum processing apparatus in a second embodiment. For each plasma processing chamber or each heat treatment chamber two gate valves are added and a robot which is specifically dedicated for transferring the processed wafer from each processing chamber into each cooling chamber is provided in each cooling chamber. Furthermore, an unprocessed-wafer-dedicated cassette 21 and a processed-wafer-dedicated cassette 33 are provided. This configuration allows the solution of the above-described problem. Incidentally, a first cooling chamber 31 and a second cooling chamber 35, which are illustrated in the schematic diagram of a vacuum processing apparatus in FIG. 12, are of the similar structure as that of the cooling chamber 1 in the first embodiment. Also, these cooling chambers allow the cooling operation in accordance with basically the same way.

Hereinafter, the explanation will be given below concerning the present second embodiment. A first gate valve 23 is opened. Then, a transfer robot 25 of a transfer chamber 24 transfers an unprocessed wafer 36 out of the unprocessed-wafer-dedicated cassette 21. After that, a second gate valve 26 is opened. Then, the unprocessed wafer 36 is transferred into a first processing chamber 27, thereby being processed therein. Next, after having been processed in the first processing chamber 27, a resultant processed wafer 37 is transferred into the first cooling chamber 31 by a cooling-chamber-transfer-dedicated robot 29 provided in the first cooling chamber 31. This is performed after a third gate valve 28 is opened. In the first cooling chamber 31, the processed wafer 37 is cooled by one of the three cooling methods in the first embodiment. Moreover, after a fourth gate valve 30 is opened, the wafer 37 cooled in the first cooling chamber 31 is transferred out of the first cooling chamber 31 by the transfer robot 25 of the transfer chamber 24. Furthermore, after a fifth gate valve 32 is opened, the wafer 37 transferred out of the first cooling chamber 31 is transferred into the processed-wafer-dedicated cassette 33. Also, these series of processing flows from the plasma processing or heat treatment to the cooling operation for the wafer 37 are also executed in accordance with basically the same way in a second processing chamber 34 and a second cooling chamber 35 applying one of the three cooling methods described in the first embodiment which are mounted at an axis-symmetrical position with reference to the transfer chamber 24. The present second embodiment avoids the processed high-temperature wafer entering into the transfer chamber 24, thus always permitting the low-temperature-state wafer to be transferred into the transfer chamber 24. As a result, the outgas generated from the processed high-temperature wafer is not exposed onto the unprocessed wafer via the transfer chamber 24. This feature makes it possible to prevent adhesion of the particles to the unprocessed wafer, or contaminating the unprocessed wafer, and allowing a reduction in the pollution onto the inner-surface wall of the transfer chamber 24.

It should be further understood by those skilled in the art that although the foregoing description has been made on embodiments of the invention, the invention is not limited thereto and various changes and modifications may be made without departing from the spirit of the invention and the scope of the appended claims.

1. A vacuum processing apparatus, comprising:
a processing chamber for processing a sample to be processed;
a cooling chamber for cooling said high-temperature sample processed in said processing chamber; and
a vacuum transfer chamber for establishing a connection between said processing chamber and said cooling chamber, a vacuum transfer robot being set up inside said vacuum transfer chamber, wherein
said cooling chamber includes
a gas-exhausting unit for reducing pressure inside said cooling chamber,
a gas-supplying unit for supplying a gas into said cooling chamber,
a pressure-controlling unit for controlling said pressure inside said cooling chamber,
a supporting unit for supporting said high-temperature sample, and
a mounting stage for proximity-holding said sample supported by said supporting unit,
said mounting stage having a temperature-adjusting unit for adjusting temperature of surface of said mounting stage into a temperature which is capable of cooling said high-temperature sample,
said supporting unit having an ascending/descending-speed varying unit.

2. The vacuum processing apparatus according to claim 1, wherein
said mounting stage has a protrusion pattern which is machined on said surface of said mounting stage.

3. A vacuum processing apparatus, comprising:
a processing chamber for processing a sample to be processed;
a cooling chamber for cooling said high-temperature sample processed in said processing chamber; and
a vacuum transfer chamber for establishing a connection between said processing chamber and said cooling chamber, a vacuum transfer robot being set up inside said vacuum transfer chamber, wherein
said cooling chamber includes
a gas-exhausting unit for reducing pressure inside said cooling chamber,
a gas-supplying unit for supplying a gas into said cooling chamber,
a pressure-controlling unit for controlling said pressure inside said cooling chamber,
a supporting unit for supporting said high-temperature sample, and
a mounting stage for mounting thereon said sample supported by said supporting unit,
said mounting stage having a temperature-adjusting unit for adjusting temperature of surface of said mounting stage into a temperature which is capable of cooling said high-temperature sample,
said supporting unit having an ascending/descending-speed varying unit.

4. A vacuum processing method using a vacuum processing apparatus,
said vacuum processing apparatus including
a processing chamber for processing a sample to be processed,
a cooling chamber for cooling said high-temperature sample processed in said processing chamber, and
a vacuum transfer chamber for establishing a connection between said processing chamber and said cooling chamber, a vacuum transfer robot being set up inside said vacuum transfer chamber,
said vacuum processing method, comprising the steps of:
transferring said high-temperature sample into said cooling chamber by using said vacuum transfer robot, said high-temperature sample being processed in said processing chamber;
supporting said sample by using a supporting unit, said sample being transferred into said cooling chamber;
supplying a gas into said cooling chamber; and
proximity-holding said sample over a mounting stage whose temperature is adjusted into a desired temperature, said sample being supported by said supporting unit.

5. The vacuum processing method according to claim 4, wherein
said proximity holding of said sample over said mounting stage is implemented by using a protrusion pattern, or said supporting unit.
